(19) United States
(12) Patent Application Publication
(10) Pub. No.: US 2011/0236825 A1
(43) Pub. Date: Sep. 29, 2011

(54) PHOTORESIST COMPOSITION AND METHOD OF FORMING PHOTORESIST PATTERN USING THE SAME

(76) Inventors: Jung-In PARK, Suwon-si (KR); Hi-Kuk Lee, Yongin-si (KR); Sang-Hyun Yun, Suwon-si (KR); Cha-Dong Kim, Cheonan-si (KR); Shi-Jin Sung, Iksan-si (KR); Sung-Yeol Jin, Iksan-si (KR); Sang-Tae Kim, Iksan-si (KR); Yong-Il Kim, Iksan-si (KR); Eun-Sang Lee, Iksan-si (KR)

(21) Appl. No.: 13/010,688

(22) Filed: Jan. 20, 2011

(30) Foreign Application Priority Data
Mar. 24, 2010 (KR) 10-2010-0026442

(51) Int. Cl. G03F 7/004; G03F 7/20

(52) U.S. Cl. 430/270.1; 430/323

(57) ABSTRACT

In a photoresist composition suitable for forming a photoresist pattern having a high profile angle, and a method of forming a photoresist pattern using the same, the photoresist composition includes an alkali-soluble resin, a quinone diazide containing compound, a compound represented by Formula 1, and a solvent:

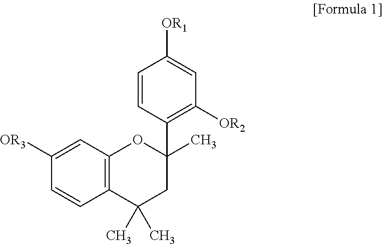

wherein R₁, R₂ and R₃ are independently H, C₁₋₄ alkyl, C₂₋₄ alkenyl, C₃₋₈ cycloalkyl, or C₆₋₁₂ aryl.

### CROSS-REFERENCE TO RELATED APPLICATION

This application claims priority from Korean Patent Application No. 10-2010-0026442 filed on Mar. 24, 2010 in the Korean Intellectual Property Office, the disclosure of which is incorporated herein by reference in its entirety.

### BACKGROUND OF THE INVENTION

1. Field of the Invention

The present invention relates to a photoresist composition and a method of forming a photoresist pattern using the same. More particularly, the present invention relates to a photoresist composition suitable for forming a photoresist pattern having a high profile angle, and a method of forming a photoresist pattern using the same.

2. Description of the Related Art

In general, in the manufacture of printed circuit boards, semiconductor wafers, or liquid crystal display panels, complicated circuit patterns are formed on a base substrate, such as an insulating substrate or a glass substrate. Photolithography is a widely used process for forming such complicated circuit patterns.

In the photolithography process, a photoresist film is formed on a base substrate, and the photoresist film is exposed to light through a photo mask. The photo mask has a transfer pattern that corresponds to a circuit pattern. The photo mask is fabricated through a high-precision technique that uses costly equipment. Accordingly, active research is being conducted on technology for exposing a photoresist film by either reducing the number of photo masks required or completely eliminating the use of a photo mask.

One method for exposing a photoresist film without a photo mask is digital exposure using a digital micromirror device (DMD). In this method, the turning on and off of a micro-mirror is controlled in a digital manner according to pixels of a transfer pattern. To create the digital exposure, several millions of micromirrors are instantaneously driven and light irradiated from a light source is allowed to be selectively reflected, thereby spatially modulating and controlling the light to form a desired pattern on a substrate.

In the digital exposure method, in order to avoid deterioration of a digital micromirror formed of aluminum, an h-line laser diode, instead of a general high-pressure mercury lamp, is used as a light source. “h-line” light typically refers to light having a wavelength of approximately 405 nm. Photoresist compositions that can form patterns having a high profile angle using the digital exposure method are needed.

### SUMMARY OF THE INVENTION

A photoresist composition suitable for forming a photoresist pattern having a high profile angle is provided.

A method of forming a photoresist pattern using a photoresist composition suitable for forming a photoresist pattern having a high profile angle is also provided.

According to one aspect, there is provided a photoresist composition that includes an alkali-soluble resin, a quinone diazide containing compound, a compound represented by Formula 1, and a solvent:

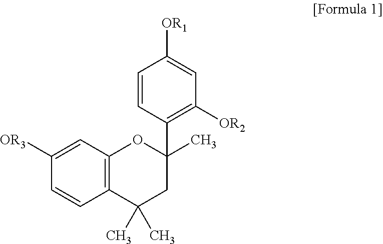

wherein R₁, R₂ and R₃ are independently H, C₁₋₄ alkyl, C₂₋₄ alkenyl, C₃₋₈ cycloalkyl, or C₆₋₁₂ aryl.

According to another aspect, there is provided a method for forming a pattern including forming a photoresist film by coating a photoresist composition on a pattern forming film, the photoresist composition including an alkali-soluble resin, a quinone diazide containing compound, a compound represented by Formula 1, and a solvent:

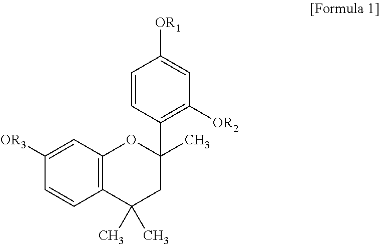

wherein R₁, R₂ and R₃ are independently H, C₁₋₄ alkyl, C₂₋₄ alkenyl, C₃₋₈ cycloalkyl, or C₆₋₁₂ aryl, exposing the photoresist film by irradiating the photoresist film with light, developing the photoresist film to form a photoresist pattern, and patterning the pattern forming film using the photoresist pattern as an etch mask.

The effects of the present invention should not be limited to the foregoing description, and additional effects and advantages will be made more apparent to those skilled in the art from the following detailed description.

### BRIEF DESCRIPTION OF THE DRAWINGS

The above and other features and advantages will become more apparent by describing various exemplary embodiments thereof with reference to the attached drawings in which:

FIG. 1 is a perspective view illustrating an exemplary digital exposure device used for forming a pattern according to an exemplary embodiment;

FIG. 2 is a detailed block diagram illustrating an exposure head shown in FIG. 1;

FIGS. 3 through 6 are cross-sectional views sequentially illustrating a method for forming a photoresist pattern according to an exemplary embodiment;

FIG. 7 is a layout view illustrating a thin film transistor (TFT) array panel manufactured by a method according to an exemplary embodiment;

FIG. 8 is a cross-sectional view of the thin film transistor (TFT) array panel of FIG. 7 taken along the line B-B′.

FIGS. 9A, 9B, 10A, 10B, 11, 12, 13A, and 13B are plan views and cross-sectional views of the thin film transistor (TFT) array panel of FIG. 7 taken along the line B-B′ during various stages of manufacturing; and

FIG. 14A is a scanning electronic microscope (SEM) view illustrating a photoresist pattern formed using a photoresist composition prepared in Example 2.

FIG. 14B is a scanning electronic microscope (SEM) view illustrating a photoresist pattern formed using a photoresist composition prepared in the Comparative Example.

### DETAILED DESCRIPTION OF THE INVENTION

Advantages and features and methods of accomplishing the same may be understood more readily by reference to the following detailed description of various exemplary embodiments and the accompanying drawings. The present invention may, however, be embodied in many different forms and should not be construed as being limited to the exemplary embodiments set forth herein. Rather, these embodiments are provided so that this disclosure will be thorough and will convey the concepts of the disclosure to those persons of ordinary skill in the art. Thus, in some exemplary embodiments, well-known methods, procedures, components, and circuitry have not been described in detail. Like reference numerals refer to like elements throughout the specification. In the drawings, the thicknesses of layers and regions may be exaggerated for clarity.

Spatially relative terms, such as “below,” “beneath,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the relevant art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments will now be described with reference to the attached drawings.

Photoresist Composition

The photoresist composition according to an embodiment includes an alkali soluble resin, a quinone diazide containing compound, a compound represented by Formula 1, and a solvent:

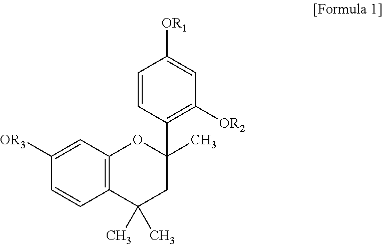

wherein R₁, R₂ and R₃ are independently H, C₁₋₄ alkyl, C₂₋₄ alkenyl. C₃₋₈ cycloalkyl, or C₆₋₁₂ aryl. The C₁₋₄ alkyl, C₂₋₄ alkenyl, C₃₋₈ cycloalkyl, or C₆₋₁₂ aryl may be unsubstituted or substituted with one or more suitable substituents, for instance, sulfonyl, imino or carbonyl groups. The C₁₋₄ alkyl can be substituted or unsubstituted and includes, for example, methyl, ethyl, n-propyl, n-butyl, isopropyl, s-butyl, t-butyl, and isobutyl. The C₂₋₄ alkenyl can be substituted or unsubstituted and includes, for example, ethenyl, propenyl, methylethenyl, 2-butenyl, and 3-butenyl, as well as, for example vinyl group. The C₃₋₈ cycloalkyl can be substituted or unsubstituted, are typically a monocylic or bicyclic ring, and includes, for example, cyclopropyl, cyclopentyl, cyclohexyl, and cycloheptyl. The C₆₋₁₂ aryl can be substituted or unsubstituted and includes, for example, phenyl and naphthyl, as well as tolyl group.

The alkali-soluble resin is soluble in an alkaline solution such as an aqueous alkali developer solution and is insoluble in pure water.

The alkali-soluble resin is not particularly limited and may be exemplified by alkali-soluble resins well known in the art. A typical example of the alkali-soluble resin may include a novolac resin. The novolac resin may be prepared by an addition-condensation reaction of a phenolic compound and an aldehyde compound.

Examples of the phenolic compound used for preparation of novolac resin may include phenol, ortho-cresol, meta-cresol, para-cresol, 2,5-xylenol, 3,5-xylenol, 3,4-xylenol, 2,3,5-trimethylphenol, 4-t-butylphenol, 2-t-butylphenol, 3-t-butylphenol, 3-ethylphenol, 2-ethylphenol, 4-ethylphenol, 3-methyl-6-t-butylphenol, 4-methyl-2-t-butylphenol, 2-naphthol, 1,3-dihydroxynaphthalene, 1,7-dihydroxynaphthalene, 1,5-dihydroxynaphthalene, and the like. These may be used individually or in combinations of two or more of the foregoing compounds.

Examples of the aldehyde compounds used for preparation of novolac resin may include formaldehyde, para-formaldehyde, acetaldehyde, propylaldehyde, benzaldehyde, phenylaldehyde, α- and β-phenyl propylaldehyde, o-, m- and p-hydroxybenzaldehyde, glutar aldehyde, glyoxal, o- and p-methyl benzaldehyde, and the like. These may be used individually or in combinations of two or more of the foregoing compounds.

The addition-condensation reaction of the phenolic compound and the aldehyde compound for preparing the novolac resin may be carried out in the presence of an acid catalyst by a conventional method. The reaction may be carried out, for example, at about 60° C. to about 250° C. for 2-3 hours. Examples of the acid catalyst may include organic acids such as oxalic acid, formic acid, trichloroacetic acid, p-toluenesulfonic acid and the like, inorganic acids such as hydrochloric acid, sulfuric acid, perchloric acid, phosphoric acid and the like, and divalent metal salts such as zinc acetate, magnesium acetate and the like can also be used.

The addition-condensation reaction may be carried out in a suitable solvent or in a bulk phase.

The average molecular weight of the novolac resin prepared by the addition-condensation reaction, as determined by gel permeation chromatography (GPC) based on monodisperse polystyrene standards, is preferably from about 2,000 to about 50,000.

An amount of the alkali-soluble resin may be 25 to 60 parts by weight, and typically 35 to 50 parts by weight, based on 100 parts by weight of the total photoresist composition.

If the amount of the alkali-soluble resin is less than 25 parts by weight, a development margin or development residues of the photoresist pattern may decrease, or heat resistance of the photoresist pattern may be lowered. If the amount of the alkali-soluble resin is greater than 60 parts by weight, sensitivity in forming the photoresist pattern may deteriorate or the formed photoresist pattern may have an unfavorable profile.

The quinonediazide group containing compound may function as a photosensitizer. The quinonediazide group containing compound may include, but are not limited to, quinonediazide group containing compounds that are known in the art as photosensitizers. Examples of the quinonediazide group containing compound may include a sulfonic acid ester of a quinone diazide derivative such as benzoquinone-1,2-diazide-4-sulfonic acid ester, naphthoquinone-1,2-diazide-4-sulfonic acid ester; a sulfonic acid chloride of a quinone diazide derivative such as benzoquinone-1,2-diazide-4-sulfonic acid chloride, naphthoquinone-1,2-diazide-4-sulfonic acid chloride, naphthoquinone-1,2-diazide-5-sulfonic acid chloride, naphthoquinone-1,2-diazide-6-sulfonic acid chloride, benzoquinone-1,2-diazide-5-sulfonic acid chloride, or the like. These may be used individually or in combinations of two or more of the foregoing compounds.

In addition, the quinonediazide group containing compound may be compounds having functional groups that can be condensed with 1,2-naphthoquinonediazide-5-sulfonyl chloride, naphtoquinone-1,2-diazide-4-sulfonate chloride, or naphtoquinone-1,2-diazide-5-sulfonate chloride. Examples of such compounds include phenol, p-methoxy phenol, hydroxyphenone, 2,4-dihydroxybenzophenone, aniline, 2,3,4,4′-tetrahydroxybenzophenone, and the like, and hydroxyl compounds are most typical.

The quinonediazide group containing compound may be used in an amount of 2 to 50 parts by weight based on 100 parts of the alkali-soluble resin, and typically in an amount of 5 to 40 parts by weight. If the amount of the quinonediazide group containing compound is less than 2 parts by weight, the development residue ratio of the photoresist pattern after development may be reduced, and the obtained photoresist pattern may have an unfavorable upper profile. If the amount of the quinonediazide group containing compound is greater than 50 parts by weight, the sensitivity in forming the photoresist pattern may deteriorate or the formed photoresist pattern may have a profile that is extremely large only at its upper portion.

The compound represented by Formula 1 improves an upper profile of the photoresist pattern after development:

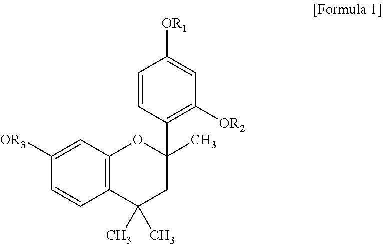

wherein R₁, R₂ and R₃ are independently H, C₁₋₄ alkyl, C₂₋₄ alkenyl, C₃₋₈ cycloalkyl, or C₆₋₁₂ aryl.

The ring structure that is the core of the compound represented by Formula 1 can be modified to absorb different wavelengths of light by using different ballast groups. The ballast material represented by Formula 1 (that is, R₁, R₂ and R₃) has high light absorption with respect to h-line light having a wavelength of about 405 nm used in the digital exposure method. Therefore, in the present exemplary embodiment, because the photoresist composition includes a compound represented by Formula 1, the photoresist film that is formed from the photoresist composition may have high sensitivity to the h-line light used in digital exposure, which may improve the upper profile of the resulting photoresist pattern. The compound represented by Formula 1 is manufactured by the method disclosed in U.S. Pat. No. 5,556,995.

An amount of the compound represented by Formula 1 may be 1 to 40 parts by weight, and preferably 5 to 30 parts by weight, based on 100 parts by weight of the photoresist composition.

If the amount of the compound represented by Formula 1 is less than 1 part by weight, the upper profile improving effect may not be noticeable. If the amount of the compound represented by Formula 1 is greater than 40 parts by weight, the shape of the photoresist pattern may be adversely affected.

As the solvent, any solvent may be used as long as it can produce a solution by dissolving an alkali-soluble resin, a quinonediazide group containing compound and the compound represented by Formula 1. Preferably, a solvent that is capable of being evaporated at an appropriate drying speed to form a uniform and planar photoresist film can be used.

Examples of the solvent may include glycol ether esters such as ethyl cellosolve acetate, methyl cellosolve acetate, propylene gylcol monomethyl cellosolve acetate, or propylene gylcol monoethyl cellosolve acetate; glycol ethers such as ethyl cellosolve, methyl cellosolve, propylene glycol monomethyl ether, and propylene glycol monoethyl ether; esters such as ethyl acetate, butyl acetate, amyl acetate, and ethyl pyruvate; ketones such as acetone, methyl isobutyl ketone, 2-heptone, and cyclohexanone; and cyclic esters such as γ-butyrol acetone. These may be used individually or in combinations of two or more of the foregoing compounds.

If necessary, the photoresist composition may further include a surfactant, an adhesion promotion agent, a plasticizer, a thickener, and other resin additives.

The surfactant is used to improve the coating performance and/or developing performance of the photosensitive composition. Such surfactants may include, for example, polyoxyethyleneoctylphenylether, polyoxyethylenenonylphenylether, F171, F172, F173 (Trade names: Dinippon Ink & Chemical, Inc.), FC430, FC431 (Trade names: Sumitomotriem, Inc.), F-477 (Trade name: Dinippon Ink & Chemical, Inc.), and KP341 (Trade name: Shinetsu Chemical Industrial, Inc.).

The adhesion promotion agent is used to improve adhesion between a substrate and a photoresist pattern. As the adhesion promotion agent, a silane coupling agent having reactive substituents such as a carboxyl group, a methacryl group, an isocyanate group, and an epoxy group may be used. Specific examples of the adhesion promotion agent include γ-methacryloxypropyltrimethoxysilane, vinyltriacetoxysilane, vinyltrimethoxysilane, γ-isocyanate propyltriethoxysilane, γ-glycidoxypropyltrimethoxysilane, β-(3,4-epoxy)cyclo hexyl ethyltrimethoxysilane, and the like. These may be used individually or in combinations of two or more of the foregoing compounds.

Hereinafter, a method for forming a pattern according to an exemplary embodiment will be described with reference to the accompanying drawings.

Method for Forming a Pattern

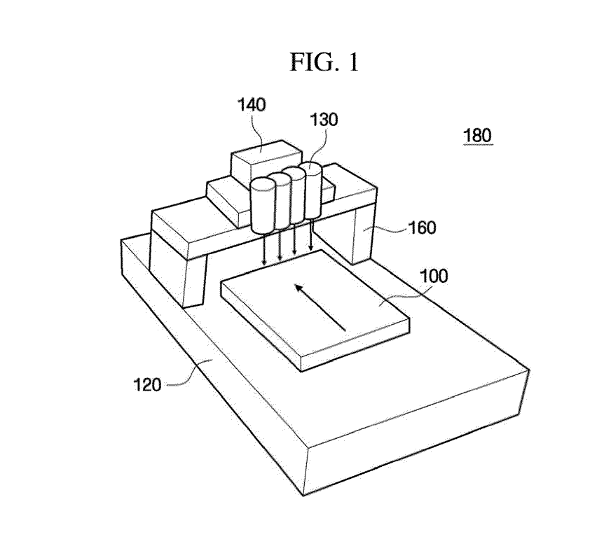

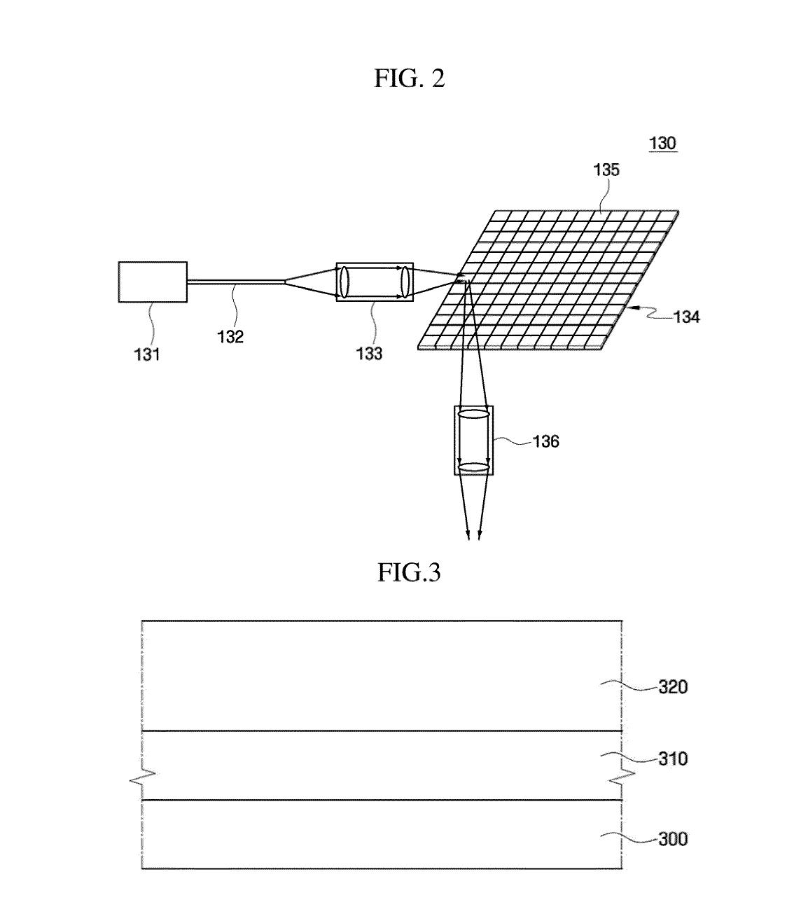

First, a digital exposure device used for forming a pattern according to an exemplary embodiment will be described with reference to FIGS. 1 and 2. FIG. 1 is a perspective view illustrating a digital exposure device used for forming a pattern according to an exemplary embodiment, and FIG. 2 is a block diagram illustrating an exposure head shown in FIG. 1.

A digital exposure device 180 includes a stage 120 for transferring a substrate 100, a first supporter 140 for supporting an exposure head 130 that supplies the substrate 100 with light, the exposure head 130, and a second supporter 160 for maintaining a gap between the substrate 100 and the exposure head 130.

The stage 120 transfers the substrate 100 to allow the substrate 100 on which a pattern is to be formed to pass under the exposure head 130. Here, the stage 120 transfers the substrate 100 with an appropriate speed so that photoresist on the substrate 100 may be photosensitized by light provided from the exposure head 130.

The first supporter 140 fixes the exposure head 130. A connection device for supplying external pattern data to the exposure head 130 may be formed in the first supporter 140.

The second supporters 160 extend from the stage 120 and are spaced a predetermined distance apart from each other to allow the first supporter 140 to be settled thereon and the substrate 100 to pass under the exposure head 130.

The exposure head 130 selectively provides light to specific areas of the substrate that are selected according to the pattern data. To this end, the exposure head 130 includes a digital micromirror device (DMD).

The DMD 134 (FIG. 2) includes a controller (not shown) having a data processor and a mirror driving controller. The controller's data processor processes the pattern data and generates a control signal that is used for driving and controlling each of the micromirrors 135 in the DMD 134 according to the pattern data. The mirror driving controller controls the reflection surface angle of each of the micromirrors 135 for each exposure head 130 based on the control signal generated by the data processor. The mirror driving controller may further include at least one laser diode 131 that supplies light to the DMD 134, and at least one optical fiber 132 that supplies the light generated from the at least one laser diode 131 to the DMD 134. Alternatively, the laser diode 131 may be formed outside the exposure head 130. In this case, the optical fiber 132 supplies the light generated from the at least one laser diode 131 to the exposure head 130.

A first lens system 133 is formed at a light entrance side of the DMD 134. The first lens system 133 focuses the light supplied from the laser diode 131 through the optical fiber 132 and supplies the focused light to the DMD 134. The first lens system 133 collimates the light emitted from an end of the optical fiber 132, and includes lenses that correct the amount of the collimated light so that it is uniformly distributed. Focus lenses for focusing the light, whose amount distribution has been corrected into the DMD 134, are also included in the first lens system 133.

The DMD 134 includes a plurality of micromirrors 135 arranged in a matrix configuration. The respective micromirrors 135 may move at a tilt angle of, for example, ±10 degrees. A highly reflective material such as aluminum is deposited on a surface of each of the plurality of micromirrors 135. The micromirrors 135 may have a reflective index of 90% or higher. Light irradiated into the DMD 134 may be reflected in a direction of in which each of the micromirrors 135 is tilted. The micromirrors 135 are tilted according to the pattern data, which is used to control the slope of the micromirrors 135 of the DMD 134.

A second lens system 136 for imaging the light reflected of off the DMD 134 is formed at an emission side of the DMD 134. The second lens system 136, disposed between the DMD 134 and the substrate 100, focuses the light reflected from the DMD 134 onto the substrate 100 and supplies the same to the substrate 100.

As described above, the digital exposure device 180 photosensitizes a predetermined region of the photoresist film that is formed on the substrate 100 using the exposure head 130 without the use of a separate mask.

Next, a method for forming a pattern according to an exemplary embodiment will be described with reference to FIGS. 3 through 6. FIGS. 3 through 6 are cross-sectional views sequentially illustrating a method for forming a photoresist pattern according to an embodiment.

Referring to FIG. 3, a substrate 300 having a film 310 for forming a pattern is prepared. A cleaning process for removing moisture or contaminants existing on a surface of the pattern forming film 310 or the substrate 300 may be selectively performed.

Next, a photoresist composition is coated onto the pattern forming film 310 to form a photoresist film 320, the photoresist composition including an alkali-soluble resin, a quinonediazide group containing compound, a compound represented by Formula 1, and a solvent. The photoresist composition may be coated by, for example, a spraying method, a roll coating method, a spin coating method, or the like.

Because the photoresist composition is substantially the same as the photoresist composition according to an exemplary embodiment described above, description of the photoresist composition here will be omitted.

After forming the photoresist film 320, a first baking process is performed by heating the substrate 300 having the photoresist film 320. The first baking process may be performed at a temperature ranging from, for example, approximately 70° C. to approximately 130° C. The solvent is removed through the first baking process, and adhesion between the pattern forming film 310 and the photoresist film 320 may be increased.

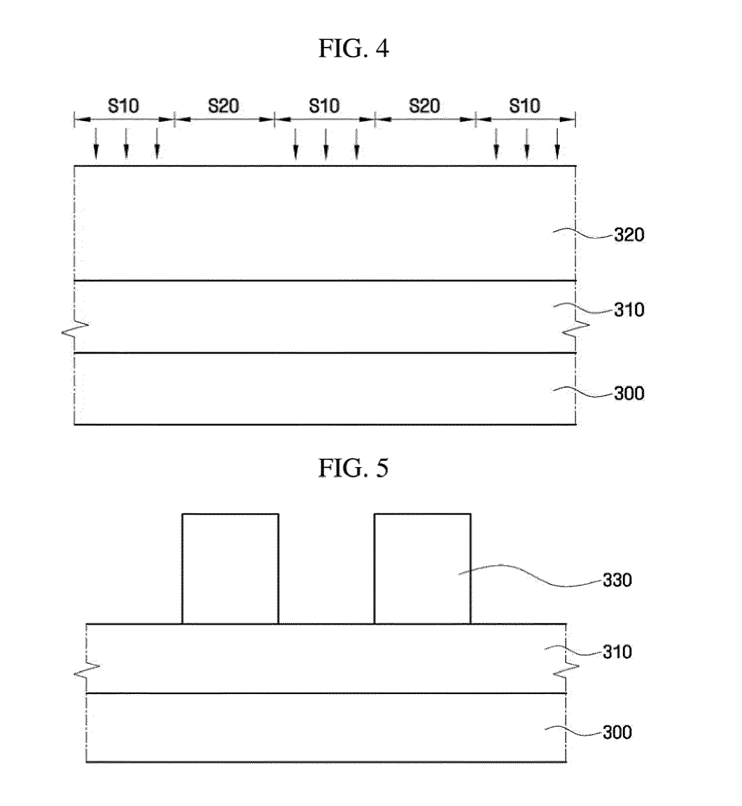

Referring to FIG. 4, the substrate 300 is exposed to light. More specifically, the substrate 300 is positioned onto the stage 120 of the digital exposure device 180 shown in FIG. 1, and the substrate 300 is irradiated with light for a predetermined time according to the pattern data, as described above. To form the photoresist pattern in photoresist film 320, the light irradiated from the exposure head 130 is irradiated into a non-patterning region S10, while the light is not irradiated into a patterning region S20. In regions of the photoresist film 320 into which the light is irradiated, the photoresist composition is changed, so that the photoresist composition in such regions 320 can be dissolved in a developer solution. The light irradiated through the digital exposure device 180 may be h-line light having a wavelength of 405 nm.

Referring to FIG. 5, the portion of the photoresist film 320 irradiated by the light, which corresponds to the non-patterning region S10, is removed using the developer solution to form a photoresist pattern 330. Because the photoresist composition according to an exemplary embodiment is a positive photoresist composition, the photoresist composition of the portion of the photoresist film 320 that is irradiated with light is removed. Any developer solution capable of removing an irradiated photoresist film that contains an alkali soluble resin and a quinone diazide containing compound may be used as the developer solution, and useful examples thereof may include a tetramethylammonium hydroxide (TMAH) solution.

A second baking process may be performed on the developed photoresist pattern 330.

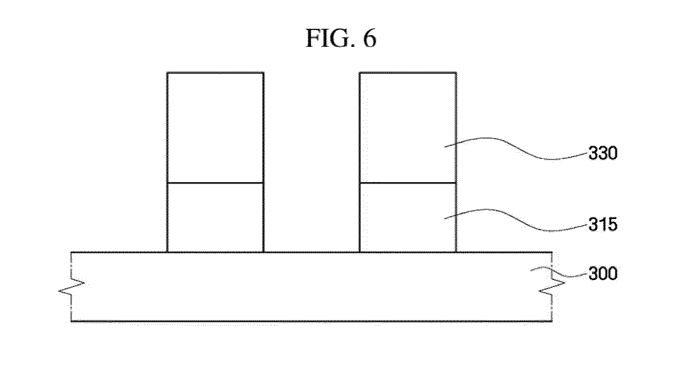

Referring to FIG. 6, the pattern forming film 310 formed under the photoresist pattern 330 is etched using the formed photoresist pattern 330 as an etch mask to form a pattern 315.

Hereinafter, a method for manufacturing a thin film transistor (TFT) array panel will be described.

Method for Manufacturing Thin Film Transistor Array Panel

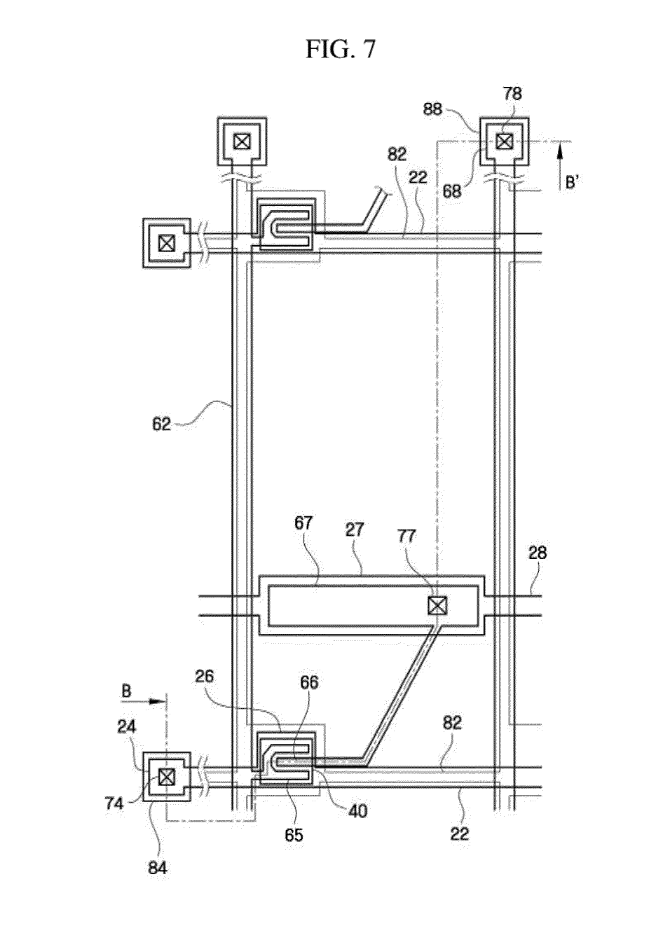

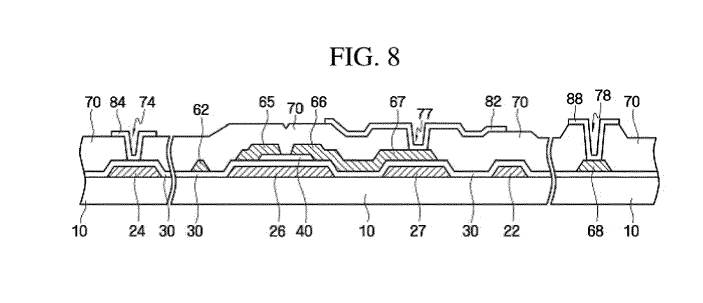

First, a structure of a thin film transistor (TFT) array panel for liquid crystal display according to an exemplary embodiment will be described with reference to FIGS. 7 and 8. FIG. 7 is a layout view illustrating a TFT array panel manufactured by a method according to an exemplary embodiment, and FIG. 8 is a cross-sectional view of the TFT array panel of FIG. 7 taken along the line B-B′.

A plurality of gate wires 22, 24, 26, 27, and 28 that transmit a gate signal are formed on an insulation substrate 10. The gate wires 22, 24, 26, 27, and 28 include a gate line 22 extending in a transverse direction; a gate pad 24 connected to the gate line 22 that applies a gate signal received from an external device and transmits the gate signal to the gate line 22; a gate electrode 26 of a thin film transistor connected to the gate line 22 and formed in the form of a protrusion from gate line 22; and a storage electrode 27 and storage electrode line 28, which are formed to be parallel with the gate line 22. The storage electrode line extends in a transverse direction across a pixel region, and is connected to the storage electrode 27 that has a width that is larger than the storage electrode line 28. The storage electrode 27 forms a storage capacitor that improves performance of charge preservation of the pixel, overlapping a drain electrode extension 67 connected to a pixel electrode 82, which will be described below. The shape and arrangement of the storage electrode 27 and the storage electrode line 28 may be modified. If storage capacitance that is generated by the overlap of the pixel electrode 82 and the gate line 22 is sufficient, the storage electrode 27 and the storage electrode line 28 may be eliminated.

The gate wires 22, 24, 26, and 27 may be made of, for example, an aluminum-containing metal such as aluminum (Al), an Al alloy, a silver-containing metal such as silver (Ag), an Ag alloy, a copper-containing metal such as copper (Cu), a Cu alloy, a molybdenum-containing metal such as molybdenum (Mo), a Mo alloy, chromium (Cr), titanium (Ti), or tantalum (Ta). In addition, the gate wires 22, 24, 26, and 27 may have a multi-layered structure including two conductive films (not shown) having different physical characteristics. Of the two conductive films, one conductive film is typically made of low resistivity metal including an Al-containing metal, an Ag-containing metal or a Cu-containing metal, for reducing signal delay or voltage drop in the gate wires 22, 24, 26, and 27. On the other hand, the other conductive film is typically made of a material having good contact characteristics with other materials, specifically indium tin oxide (ITO) or indium zinc oxide (IZO), such as a Mo-containing material, Cr, Ti, Ta, or the like. An exemplary combination of these conductive films may include a Cr lower layer and an Al (alloy) upper layer, and an Al (alloy) lower layer and a Mo (alloy) upper layer, but aspects of the present invention are not limited thereto. Alternatively, the gate wires 22, 24, 26, and 27 may be made of various metals and conductive materials.

The storage electrode line 28 may also be formed with the same material as the other gate wires 22, 24, 26, and 27.

A gate insulating film 30 made of, for example, silicon nitride (SiNₓ) is formed on the gate wires 22, 24, 26, 27 and 28, and the substrate 10.

A semiconductor layer 40 made of, for example, hydrogenated amorphous silicon or polycrystalline silicon is formed on the gate insulating film 30 of the gate electrode 26. The semiconductor layer 40 may have various shapes, including, for example, an island shape or a line shape.

Data wires 62, 65, 66, 67, and 68 are formed on the semiconductor layer 40 and the gate insulating film 30. The data wires 62, 65, 66, 67, and 68 include a data line 62 formed in a longitudinal direction across the gate line 22, which, with the gate lines 22, defines a pixel; a source electrode 65 that branches off from the data line 62 and extends to the upper portion of the oxide semiconductor layer 40; a data line pad 68 connected to one end of the data line 62; a drain electrode 66 that is separated from the source electrode 65 to face the source electrode 65 across the gate electrode 26 on the oxide semiconductor layer 40; and an electrode extension 67 that has a large area and extends from the drain electrode 66, overlapping the storage electrode 27.

The data wires 62, 65, 66, 67, and 68 are typically formed of a refractory material such as, for example, Cr, a Mo-containing material, Ta, or Ti. The data wires 62, 65, 66, 67, and 68 may have a multi-layered structure including a lower layer (not shown) made of, for example, a refractory metal made of and an upper layer (not shown) made of a low resistivity metal such as, for example, a Mo-containing metal. Examples of the multi-layered structure may include a structure including a Cr lower layer and an Al (alloy) upper layer, a structure including an Al (alloy) lower layer and a Mo upper layer, and a triple-layered structure including Mo—Al—Mo layers.

The drain electrode 66 faces the source electrode 65 across the gate electrode 26 and overlaps at least a portion the semiconductor layer 40.

The drain electrode extension 67 is formed to overlap the storage electrode 27 with the gate insulating film 30 disposed between the drain electrode extension 67 and the storage electrode 27, so that the drain electrode extension 67 and the storage electrode 27 may form storage capacitance. When the storage electrode 27 is eliminated, the drain electrode extension 67 is also eliminated.

A passivation film 70 is formed on the entire surface of the data wires 62, 65, 66, 67, and 68 and the exposed semiconductor layer 40. Here, the passivation film 70 is typically made of, for example, a photosensitive organic material having a good flatness characteristic, or a low dielectric insulating material such as, for example, a-Si:C:O and a-Si:O:F formed by plasma enhanced chemical vapor deposition (PECVD), or an inorganic insulator such as, for example, silicon nitride (SiNₓ). When the passivation film 70 is made of an organic material, an insulation layer (not shown) made of, for example, silicon nitride (SiNₓ) or silicon oxide (SiO₂) may further be provided under the organic layer to prevent an organic material of the passivation film 70 from contacting an exposed portion of the semiconductor layer 40 between the source electrode 65 and the drain electrode 66.

Contact holes 77 and 78 that expose the drain electrode extension portion 67 and the data pad 68 are formed in the passivation layer 70. A contact hole 74 that exposes the gate pad 24 is formed in the passivation layer 70 and the gate insulating film 30. A pixel electrode 82 that is electrically connected to the drain electrode 66 via the contact hole 77 is disposed on a portion of the passivation layer 70 corresponding to each pixel. Electric fields are generated between the pixel electrode 82 supplied with the data voltages and a common electrode of an upper display substrate, which determine an orientation of liquid crystal molecules in the LC layer between the pixel electrode 82 and the common electrode.

An auxiliary gate pad 84 and an auxiliary data pad 88 connected to the gate pad 24 and the data pad 68 via the contact holes 74 and 78, respectively, are also disposed on the passivation layer 70. The pixel electrode 82, the auxiliary gate pad 84, and the auxiliary data pad 88 are made of, for example, a transparent conductor such as indium tin oxide (ITO) or indium zinc oxide (IZO).

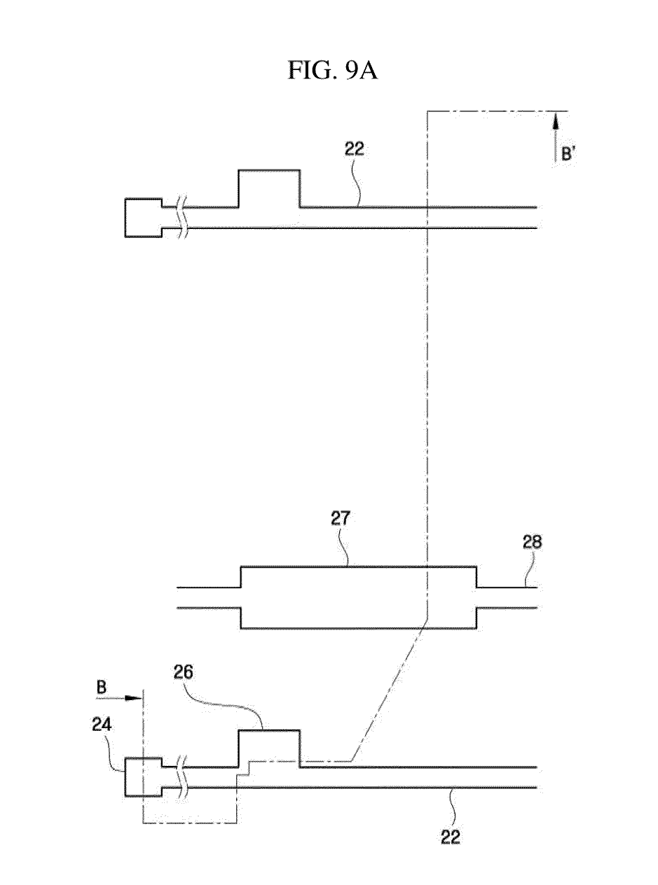

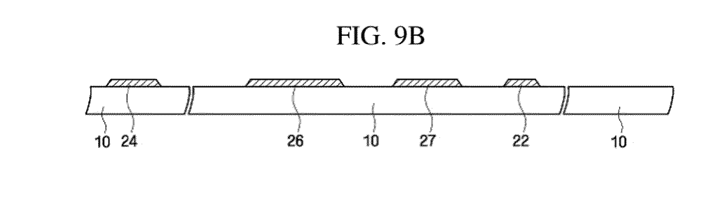

Hereinafter, a method of manufacturing a TFT array panel according to an exemplary embodiment will be described with reference to FIGS. 7 through 13B. FIG. 7 is a layout view illustrating a thin film transistor (TFT) array panel manufactured by a method according to an exemplary, and FIGS. 9A through 13 are plan views and cross-sectional views of the thin film transistor (TFT) array panel of FIG. 7 taken along the line B-B′.

First, referring to FIGS. 9A and 9B, gate wires 22, 24, 26, 27 and 28 are formed on a substrate 10. A conductive film for gate wires may be formed using, for example, sputtering. When patterning the gate wires 22, 24, 26, 27 and 28, wet etching or dry etching may be used. When wet etching is used, an etching solution such as phosphoric acid, nitric acid or acetic acid may be used. When dry etching is used, a chlorine-containing etching gas such as Cl₂ or BCl₃ may be used.

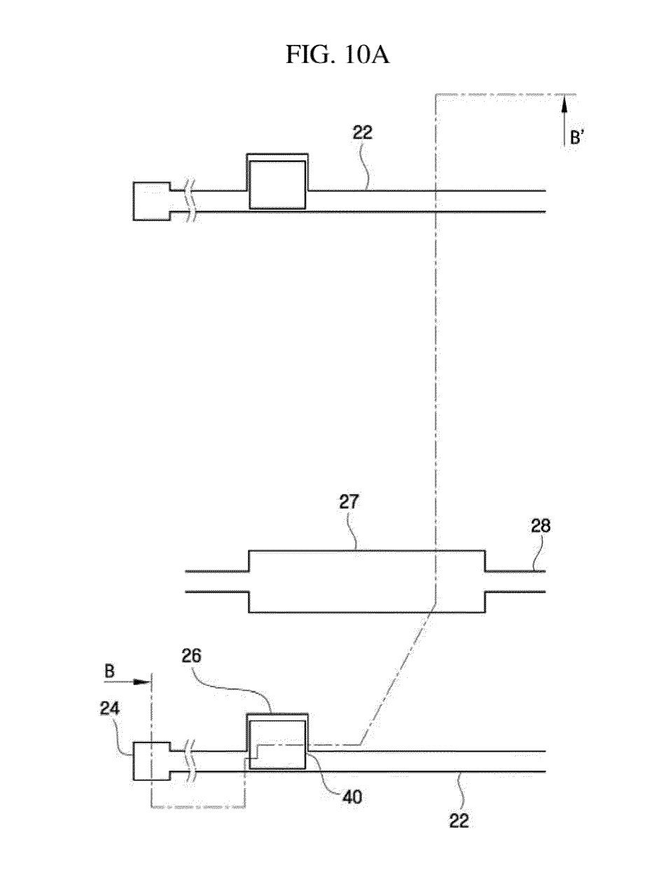

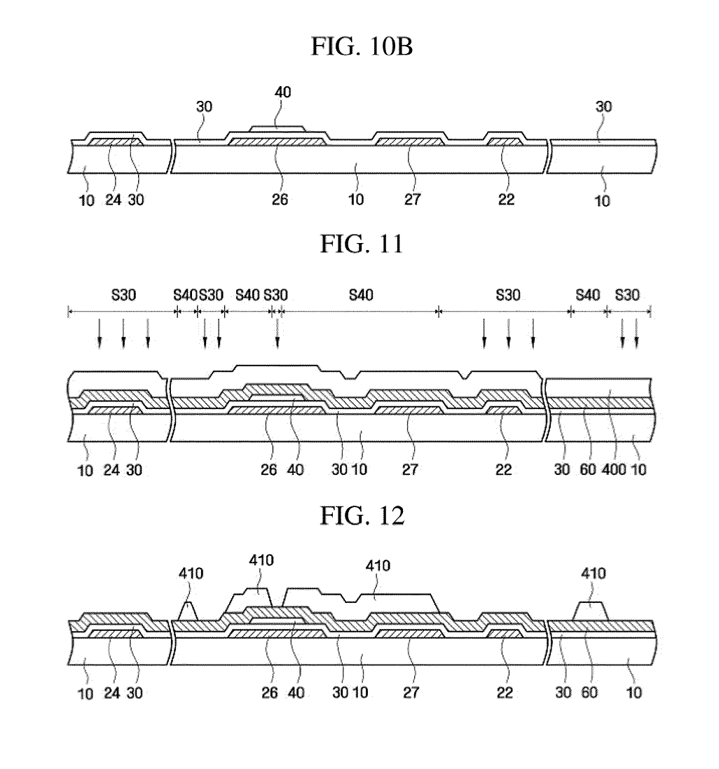

Then, referring to FIGS. 10A and 10B, gate insulating film 30 made of silicon nitride is formed on a substrate and gate wires 22, 24, 26, 27 and 28 by plasma enhanced chemical vapor deposition (PECVD), or reactive sputtering. Next, a semiconductor layer 40 is formed on gate insulating film 30.

Referring to FIG. 11, a conductive film 60 for data wires is formed on the gate insulating film 30 and the semiconductor layer 40. Next, a photoresist composition is coated on the data wire conductive film 60 to form a photoresist film 400, the photoresist composition including an alkali-soluble resin, a quinonediazide group containing compound, a compound represented by Formula 1, and a solvent. The photoresist composition for forming the photoresist film 400 may be coated by, for example, a spraying method, a roll coating method, a spin coating method, or the like.

The photoresist composition and method for forming a photoresist pattern are substantially the same as described above, therefore descriptions thereof are omitted here.

The substrate 10 having the photoresist film 400 is exposed to light. Regions S30 in which data wires 62, 65, 66, 67, and 68 are not formed is irradiated with light by an exposure head (130 of FIG. 1) of a digital exposure device, but regions S40 in which the data wires 62, 65, 66, 67, and 68 are to be formed is not irradiated with light.

Referring to FIG. 12, the light irradiated portion of the photoresist film 400 is removed using a developer solution to form a photoresist pattern 410.

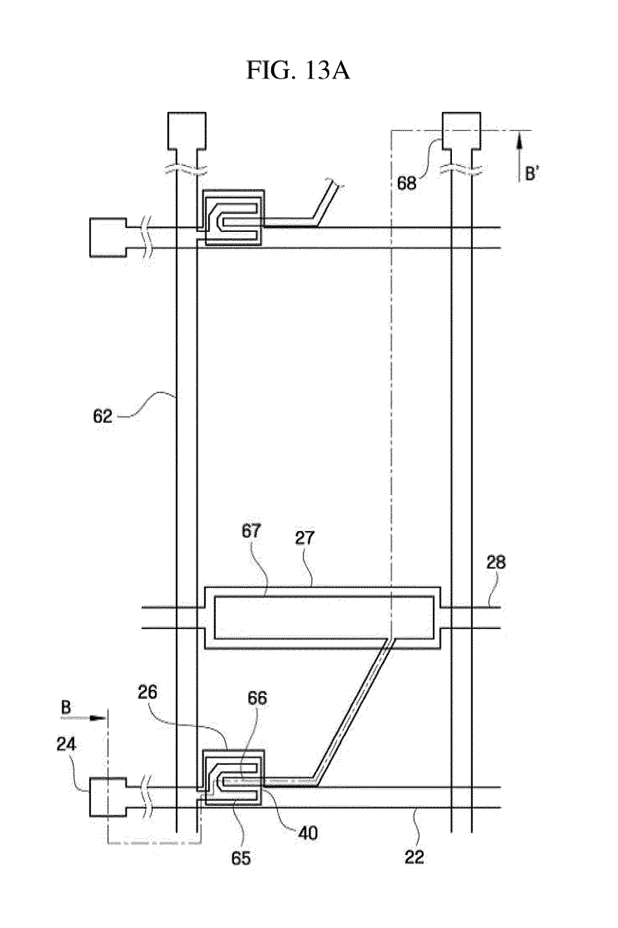

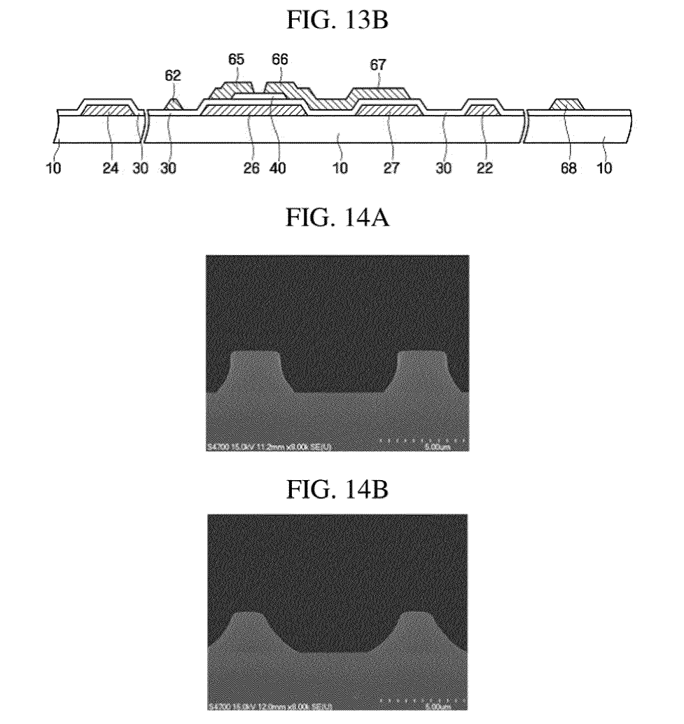

Referring to FIGS. 13A and 13B, the data wire conductive film 60 is etched using the formed photoresist pattern 410 as an etch mask to form the data wires 62, 65, 66, 67, and 68.

Referring to FIG. 8, a passivation film 70 is formed using PECVD or reactive sputtering.

Next, the gate insulating film 30 and the passivation film 70 are patterned using photolithography to form contact holes 74, 77, and 78, which expose the gate pad 24, the drain electrode extension 67 and the data pad 68.

Next, a transparent conductor film is deposited and subjected to photolithography to form a pixel electrode connected to the drain electrode 66 via the contact hole 77, and an auxiliary gate pad 84 and an auxiliary data pad 88 connected to the gate pad 24 and the data pad 68 via the contact holes 74 and 78, respectively.

Although the method for fabricating the TFT array panel in which data wires are formed using the photoresist pattern formed with the photoresist composition is described in the illustrative embodiment, aspects of the present invention are not limited thereto. For instance, another electrode pattern or a semiconductor layer pattern of the TFT array panel may be formed using the photoresist pattern formed of the photoresist composition.

Hereinafter, examples of the photoresist composition are presented. It will be understood that the following examples are only for the understanding of the disclosure and the scope of the present invention is not limited thereto.

### Example 1

### Preparation of Novolac Resin

A phenol mixture including m-cresol and p-cresol mixed in a weight ratio of 60:40 was prepared and formalin was added to the mixture, followed by a condensation reaction in the presence of an oxalic acid catalyst by a conventional method, thereby obtaining a cresol novolac resin. The cresol novolac resin was fractionated and cut to exclude a high molecular weight range and a low molecular weight range, yielding a novolac resin having a weight average molecular weight of approximately 15,000, which is to be referred to hereinafter as novolac resin 1.

A phenol mixture including m-cresol and p-cresol were mixed in a weight ratio of 60:40 was prepared and formalin was added to the mixture and formalin was added thereto, followed by a condensation reaction in the presence of an oxalic acid catalyst by a conventional method, thereby obtaining a cresol novolac resin. The cresol novolac resin was fractionated and cut to exclude a high molecular weight range and a low molecular weight range, yielding a novolac resin having a weight average molecular weight of 16,000, which is to be referred to hereinafter as novolac resin 2.

Preparation of Photoresist Composition

A photoresist composition was formed by mixing (1) as an alkali-soluble resin, 45 parts by weight of a novolac resin mixture that included novolac resin 1 and novolac resin 2 mixed in a weight ratio of 40:60, (2) as a quinonediazide group containing compound, 3.7 parts by weight of an ester compound of 2,3,4,4′-tetrahydroxybenzophenone and 1,2-naphtoquinonediazide-5-sulfonyl chloride, (3) 1 part by weight of a compound represented by Formula 1, (4) as a surfactant, 0.2 parts by weight of F-477 (Trade name: Dinippon Ink & Chemical, Inc.), and (5) a remainder of a solvent including proplyleneglycone monoether acetate and proplyleneglycone monomethyl ether mixed in a weight ratio of 70:30. The formed photoresist composition was filtered using a 0.2 μm membrane filter.

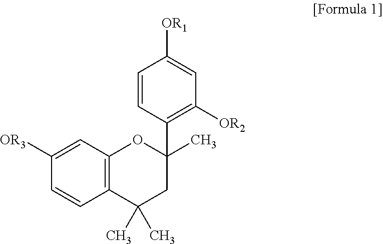

wherein R₁, R₂ and R₃ are each represented by the following formula 2:

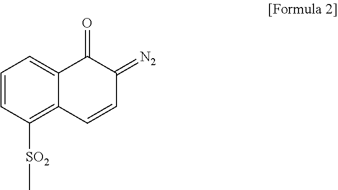

### Example 2

A photoresist composition was formed in the same manner as in Example 1, except that the compound represented by Formula 1 was used in an amount of 2.5 parts by weight.

### Example 3

A photoresist composition was formed in the same manner as in Example 1, except that the compound represented by Formula 1 was used in an amount of 3 parts by weight.

### Comparative Example

A photoresist composition was formed in the same manner as in Example 1, except that the compound represented by Formula 1 was not included.

Evaluation of Photoresist Pattern

Photoresist patterns were formed using photoresist compositions prepared in Examples 1 to 3 and the Comparative Example. More specifically, each of the photoresist compositions prepared in Examples 1 to 3 and the Comparative Example was coated on a substrate, followed by vacuum drying and pre-baking, thereby forming a film. Thereafter, the formed film was exposed to h-line light using a digital exposure device. Then, the resultant product was developed using an aqueous solution of 2.38 parts by weight of tetramethylammonium hydroxide (TMAH), and the developed pattern was post-backed.

The developed photoresist pattern was observed using a scanning electronic microscope (SEM) and evaluated in view of effective sensitivity, resolution, development residue ratio, pattern shape, and heat resistance. Evaluation results are shown in Table 1. The various characteristics of each photoresist pattern, as shown in Table 1, were evaluated in the following manner:

1. Effective sensitivity: Exposure dose required for forming a 10 μm line-and-space pattern having 1:1 aspect ratio;

2. Resolution: Minimum exposure line width of a line-and-space pattern resolved when exposure is performed with the effective sensitivity;

3. Development residue ratio: Photoresist film thickness ratio before and after development;

4. Pattern shape: Upper portion of a photoresist pattern were observed by SEM, and as the result of the observation, the patterns were judged visually as being good (∘), average (Δ) and bad (X); and

5. Heat resistance: Photoresist patterns were treated in a hot plate under the treatment conditions of 150° C. and 150 seconds, pattern shapes before and after treatment were observed by SEM, and as the result of the observation, the pattern shapes were visually judged as ⊚ when they are not changed, ∘ when they are slightly changed, Δ when they are moderately changed, and X when they are severely changed.

TABLE 1

| | Effective | | Development | | |
|---|---|---|---|---|---|
| | Sensitivity | Resolution | Residue ratio | Pattern | Heat |
| | (mJ) | (μm) | (%) | Shape | Resistance |
| Example 1 | 37.5 | 5 | 98 | ∘ | ∘ |
| Example 2 | 38 | 5 | 98 | ∘ | ∘ |
| Example 3 | 36 | 5 | 98 | ∘ | ∘ |
| Comparative | 58 | 5 | 98 | Δ | Δ |
| Example | | | | | |

As shown by the results in Table 1, the photoresist patterns formed using the photoresist compositions prepared in Examples 1 to 3 were better than the photoresist composition prepared in the Comparative Example, with respect to pattern shape and heat resistance, without lowering the development residue ratio.

FIG. 14A is a scanning electronic microscope (SEM) view illustrating a photoresist pattern formed using a photoresist composition prepared in Example 2, and FIG. 14B is a scanning electronic microscope (SEM) view illustrating a photoresist pattern formed using a photoresist composition prepared in the Comparative Example.

Referring to FIGS. 14A and 14B, the photoresist pattern formed by the photoresist composition prepared in Example 2 had a good profile.

While the present invention has been particularly shown and described with reference to exemplary embodiments thereof, it will be understood by those of ordinary skill in the art that various changes in form and details may be made therein without departing from the spirit and scope of the present invention. It is therefore desired that the present embodiments be considered in all respects as illustrative and not restrictive.

What is claimed is:

1. A photoresist composition comprising:
an alkali-soluble resin;
a quinone diazide containing compound;
a compound represented by Formula 1; and
a solvent: 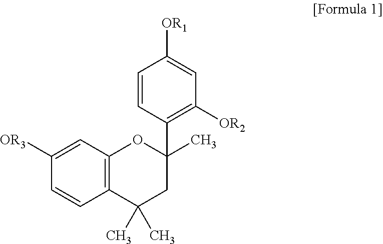
wherein R₁, R₂ and R₃ are independently H, C₁₋₄ alkyl, C₂₋₄ alkenyl, C₃₋₈ cycloalkyl, or substituted or unsubstituted C₆₋₁₂ aryl.

2. The photoresist composition of claim 1, wherein about 1 to 40 parts by weight of the compound represented by Formula 1 is included in the photoresist composition.

3. The photoresist composition of claim 2, wherein about 25 to 60 parts by weight of the alkali-soluble resin is included in the photoresist composition.

4. The photoresist composition of claim 3, wherein about 2 to 50 parts by weight of the quinone diazide containing compound is included in the photoresist composition based on 100 parts by weight of the alkali-soluble resin.

5. The photoresist composition of claim 1, wherein the compound represented by Formula 1 absorbs h-line light having a wavelength of 405 nm.

6. The photoresist composition of claim 1, further comprising at least one selected from the group consisting of a surfactant, an adhesion promotion agent, a plasticizer, a thickener, and other resin additives.

7. The photoresist composition of claim 1, wherein the photoresist composition is a positive photoresist composition.

8. The photoresist composition of claim 1, wherein the alkali-soluble resin is a novolac resin having a weight average molecular weight of 2,000 to 50,000 based on monodisperse polystyrene standards.

9. A method for forming a pattern comprising:
forming a photoresist film by coating a photoresist composition on a pattern forming film, the photoresist composition including an alkali-soluble resin, a quinone diazide containing compound, a compound represented by Formula 1, and a solvent: 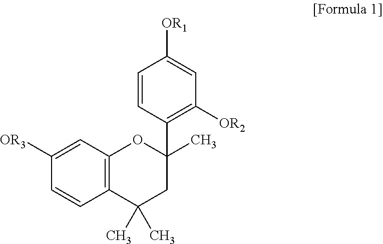
wherein R₁, R₂ and R₃ are independently H, C₁₋₄ alkyl, C₂₋₄ alkenyl, C₃₋₈ cycloalkyl, or substituted or unsubstituted C₆₋₁₂ aryl;
exposing the photoresist film by irradiating the photoresist film with light;
developing the photoresist film to form a photoresist pattern; and
patterning the pattern forming film using the photoresist pattern as an etch mask.

10. The method of claim 9, wherein about 1 to 40 parts by weight of the compound represented by Formula 1 is included in the photoresist composition.

11. The method of claim 10, wherein about 25 to 60 parts by weight of the alkali-soluble resin is included in the photoresist composition.

12. The method of claim 11, wherein about 2 to 50 parts by weight of the quinone diazide containing compound is included in the photoresist composition based on 100 parts by weight of the alkali-soluble resin.

13. The method of claim 9, wherein the irradiating the photoresist film with light comprises irradiating light using a digital exposure device including a digital micromirror device.

14. The method of claim 13, wherein the light is h-line light having a wavelength of 405 nm.

15. The method of claim 9, wherein the photoresist pattern is formed at an unexposed region onto which the light is not irradiated.

16. The method of claim 9, wherein the photoresist composition further comprises at least one selected from the group consisting of a surfactant, an adhesion promotion agent, a plasticizer, an enhancer, and a resin.

17. The method of claim 9, wherein the alkali-soluble resin is a novolac resin having a weight average molecular weight of 2,000 to 50,000 based upon monodisperse polystyrene standards.
